(19) United States
(12) Patent Application Publication
(10) Pub. No.: US 2011/0086313 A1
(43) Pub. Date: Apr. 14, 2011

(54) METHOD AND SYSTEM OF MANUFACTURING SEMICONDUCTOR DEVICE

(76) Inventors: Tomoya OORI, Mie-ken (JP); Shinichi ITO, Kanagawa-ken (JP)

(21) Appl. No.: 12/823,821

(22) Filed: Jun. 25, 2010

(30) Foreign Application Priority Data
Oct. 8, 2009 (JP) 2009-233986

(51) Int. Cl. G03F 7/20; G03B 27/52

(52) U.S. Cl. 430/312; 430/319; 355/27

(57) ABSTRACT

In one embodiment, a method is disclosed for manufacturing a semiconductor device. The method can forms a resist film on a substrate. The method can expose a portion of the resist film. The portion is formed on a device area of the substrate and the device area includes a center portion of the substrate. After the exposing the device area, the method can apply a reaction control process for controlling expansion of a reacted region in the resist film. After the applying the reaction control process, the method can expose another portion of the resist film and the another portion is formed on a peripheral area surrounding the device area. After the exposing the peripheral area, the method can heat the resist film, and after the heating, the method can develop the resist film.

### CROSS-REFERENCE TO RELATED APPLICATIONS

This application is based upon and claims the benefit of priority from the prior Japanese Patent Application No. 2009-233986, filed on Oct. 8, 2009; the entire contents of which are incorporated herein by reference.

### FIELD

Embodiments described herein relate generally to a method and system of manufacturing semiconductor device.

### BACKGROUND

Semiconductor devices have been heretofore manufactured by applying fine processes to a semiconductor wafer and an interlayer dielectric and the like formed on the semiconductor wafer. These fine processes are usually made through photolithography. Specifically, a resist film is formed on a semiconductor wafer; this resist film is subsequently exposed and developed to thereby obtain a resist pattern; and the subsequent processes are performed using this resist pattern as a mask.

An exposure apparatus for exposing a resist film requires far more precise technology than an apparatus for performing processing such as forming and developing the resist film. For this reason, the exposure apparatus is usually provided separately from a coating/developing apparatus for performing processing such as forming and developing the resist film. Generally, there is a difference between the throughput of the coating/developing apparatus and the throughput of the exposure apparatus. For this reason, in the case of performing the formation, the exposure, and the development, of the resist film as an in-line process in this order, an apparatus whose throughput is the slowest determines the productivity of a semiconductor device. Against this background, for the purpose of enhancing the productivity of a semiconductor device, it is necessary to adjust the ratio between the number of coating/developing apparatuses and the number of exposure apparatuses, and to flexibly manage the processes off-line.

However, this approach involves the following problem. Specifically, when wafers are transferred between the coating/developing apparatus and the exposure apparatus, there occurs variation among the wafers in waiting time. This causes dimensions of their resist patterns to vary accordingly (for instance, refer to JP-A 3-154324 (Kokai)).

### BRIEF DESCRIPTION OF THE DRAWINGS

FIG. 1 is a block diagram illustrating a semiconductor device manufacturing system according to a first embodiment;

FIGS. 2A to 2C are perspective views illustrating a wafer and a resist processed in the first embodiment;

FIG. 3 is a flowchart illustrating the semiconductor device manufacturing method according to the first embodiment;

FIG. 4 is a block diagram illustrating a semiconductor device manufacturing system according to a comparative example;

FIG. 5 is a flowchart illustrating the semiconductor device manufacturing method according to the comparative example;

FIG. 6 is a block diagram illustrating a semiconductor device manufacturing system according to a second embodiment;

FIG. 7 is a flowchart illustrating the semiconductor device manufacturing method according to the second embodiment;

FIG. 8 is a block diagram illustrating a semiconductor device manufacturing system according to a third embodiment;

FIG. 9 is a flowchart illustrating the semiconductor device manufacturing method according to the third embodiment;

FIG. 10 is a block diagram illustrating a semiconductor device manufacturing system according to a fourth embodiment;

FIG. 11 is a block diagram illustrating a semiconductor device manufacturing system according to a fifth embodiment;

FIG. 12A is a perspective cross-sectional view showing a transfer storage container according to the fifth embodiment, and FIG. 12B is a partially magnified cross-sectional view of the area A shown in FIG. 12A;

FIG. 13 is a flowchart illustrating the semiconductor device manufacturing method according to a sixth embodiment; and

FIG. 14 is a flowchart illustrating the semiconductor device manufacturing method according to a seventh embodiment.

### DETAILED DESCRIPTION

In one embodiment, a method for manufacturing a semiconductor device is disclosed. The method can forms a resist film on a substrate. The method can expose a portion of the resist film. The portion is formed on a device area of the substrate and the device area includes a center portion of the substrate. After the exposing the device area, the method can apply a reaction control process for controlling expansion of a reacted region in the resist film. After the applying the reaction control process, the method can expose another portion of the resist film and the another portion is formed on a peripheral area surrounding the device area. After the exposing the peripheral area, the method can heat the resist film, and after the heating, the method can develop the resist film.

Hereinafter, referring to the drawings, descriptions will be provided for embodiments of the invention.

First of all, descriptions will be provided for a first embodiment of the invention.

A characteristic of a semiconductor device manufacturing method according to this embodiment lies in a photolithographic process. In addition, a semiconductor device manufacturing system according to this embodiment is a set of units for carrying out this photolithographic process. In this embodiment, a semiconductor device is manufactured through processing a wafer. A “device area” and a “peripheral area” are provided in the wafer. The device area is an area in which the semiconductor device is to be formed. The peripheral area is an area other than the device area, for instance, an area surrounding the device area. In addition, the device area is set so as to include a center portion of the wafer.

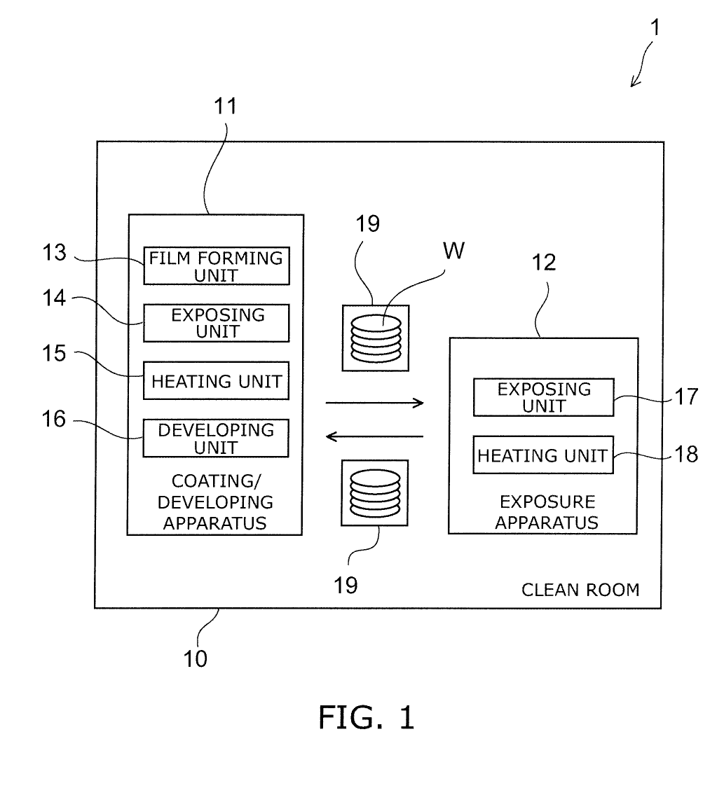

FIG. 1 is a block diagram illustrating the semiconductor device manufacturing system according to this embodiment.

As shown in FIG. 1, a clean room 10 is installed in the semiconductor device manufacturing system 1 according to this embodiment. A coating/developing apparatus 11 and an exposure apparatus 12 for the device area are installed inside the clean room 10. The coating/developing apparatus 11 includes therein a film forming unit 13, an exposing unit 14 for the peripheral area, a heating unit 15, and a developing unit 16. The film forming unit 13 forms a resist film by coating and baking a resist material on the wafer. The exposing unit 14 exposes a portion of the resist film which is formed in the peripheral area of the wafer. The heating unit 15 heats the resist film. The developing unit 16 develops the resist film. These units are fixedly installed inside the coating/developing apparatus 11. When an operator programs a process sequence, the wafer is caused to undergo predetermined processes while being transferred from one unit to another in the predetermined sequence. Thereby, the coating/developing apparatus 11 is capable of processing each single wafer uninterruptedly, and accordingly managing time needed between the processes exactly. For instance, the exposing unit 14 and the heating unit 15 are respectively capable of exposing and heating each single wafer uninterruptedly. This allows precise management of time needed from the exposing process by the exposing unit 14 to the heating process by the heating unit 15.

On the other hand, an exposing unit 17 and a heating unit 18 are installed in the exposure apparatus 12. The exposing unit 17 exposes another portion of the resist film which is formed on the device area of the wafer. The heating unit 18 heats the resist film. The exposing unit 17 and the heating unit 18 are fixedly installed inside the exposure apparatus 12, and carry out their respective processes in a programmed sequence. Thereby, the exposure apparatus 12 is capable of causing the heating unit 18 to heat the wafer, which has been exposed by the exposing unit 17, uninterruptedly. Accordingly, the exposure apparatus 12 is capable of exactly managing time from the exposing process to the heating process. Each of the heating unit 15 and the heating unit 18 perform post-exposure bake (PEB) to accelerate reaction of an acid which occurs in the resist film due to the exposure. Each of the heating unit 15 and the heating unit 18 performs a heating process at a temperature in a range of 80 to 190° C., for instance, or more specifically, at a temperature of 100° C., for instance.

The exposing unit 17 included in the exposure apparatus 12 for the device area exposes the device area of the wafer to thereby obtain a pattern, which is used to form the semiconductor device. The exposing unit 17 is capable of exposure to obtain a fine pattern. The exposing unit 17 is, for instance, an exposing unit of an immersion type. By contrast to this, the exposing unit 14 for the peripheral area exposes the peripheral area of the wafer to thereby obtain a dummy pattern for adjusting a coverage factor. The exposure precision of the exposing unit 14 for the peripheral area may be lower than that of the exposing unit 17 in the exposure apparatus 12. Note that the dummy pattern for adjusting the coverage factor is a pattern used to adjust a coverage factor of the resist pattern on the peripheral area corresponding to a coverage factor of the resist pattern on the device area. The forming of the dummy pattern for adjusting the coverage factor allows reduction of a variation in the process conversion difference during a process, such as an etching process, which is performed after the photolithographic process.

A wafer W is transferred between the coating/developing apparatus 11 and the exposure apparatus 12 by a transfer storage container 19. The transfer storage container 19 contains therein and transfers multiple wafers W, for instance, 25 wafers at one time.

Next, descriptions will be provided for the operation of the manufacturing system 1 configured in the foregoing manner, in other words, for a semiconductor device manufacturing method according to this embodiment.

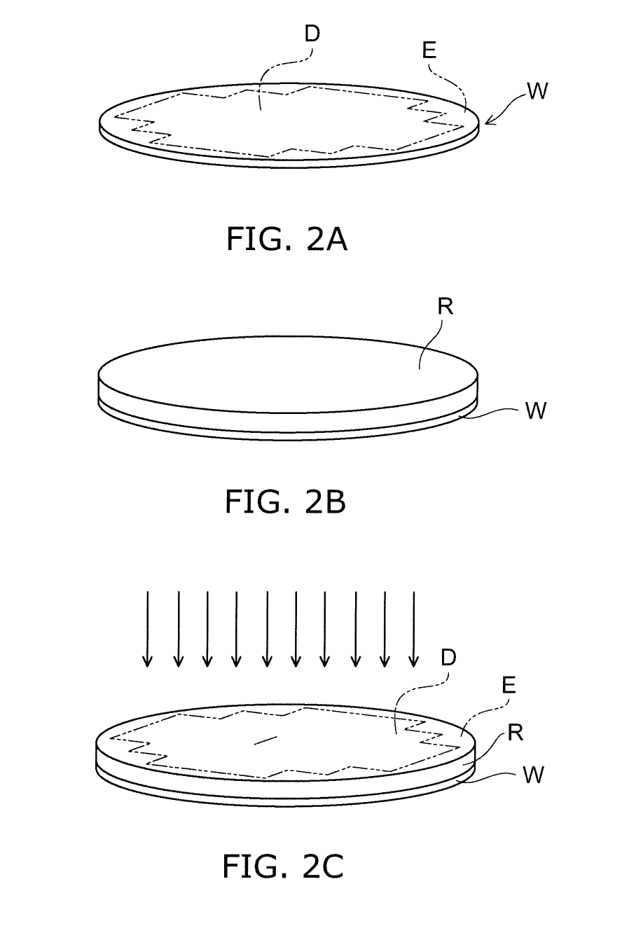

FIGS. 2A to 2C are perspective views illustrating of a wafer and a resist which are processed in this embodiment.

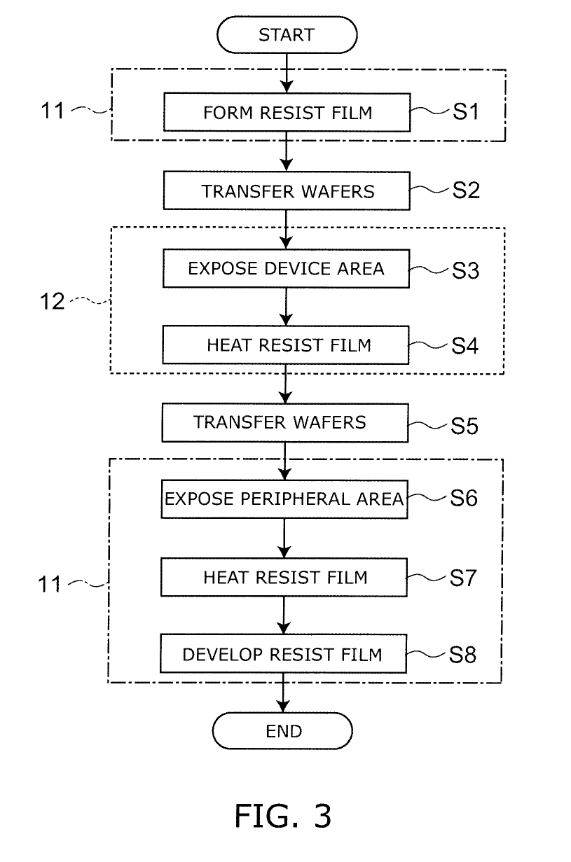

FIG. 3 is a flowchart illustrating the semiconductor device manufacturing method according to this embodiment.

Note that in FIG. 3, steps surrounded by an alternate long and short dash line indicate processes performed by a coating/developing apparatus, whereas steps surrounded by a broken line indicate processes performed by an exposure apparatus for the device area. This is the case with the other flowcharts, which will be described later.

First of all, as shown in FIG. 2A, the wafer W is prepared as a substrate. A device area D and a peripheral area E are provided in the wafer W. The device area D is an area in which the semiconductor device is to be formed. The peripheral area E is an area surrounding the device area D, and no semiconductor device is formed in the peripheral area E. An interlayer dielectric film (not illustrated) and the like may be formed on the wafer W. In addition, the temperature inside the clean room 10 is set to the room temperature, or to 23° C., for instance.

Subsequently, as shown in FIG. 2B and as indicated by step 51 of FIG. 3, the film forming unit 13 installed inside the coating/developing apparatus 11 in the manufacturing system 1 coats a resist material throughout the top surface of the wafer W, and thereafter bakes the wafer W. Thereby, a resist film R is formed on the wafer W. In this respect, the resist material is, for instance, an ArF chemically-amplified resist material of a positive type, and the film thickness of the resist film R is, for instance, 100 nm (nanometers). Note that, in a case where an interlayer dielectric film is formed on the wafer W, the resist film R is formed on this interlayer dielectric film.

Afterward, as indicated by step S2 of FIG. 3, each batch of a predetermined number of wafers W, 25 wafers W, for instance, is contained in the transfer storage container 19, and is thus transferred from the coating/developing apparatus 11 to the exposure apparatus 12. During this operation, depending on an usage of the exposure apparatus 12, the wafers W may be unable to be set inside the exposure apparatus 12 immediately after their transfer, and a waiting time may accordingly occur.

After that, as shown in FIG. 2C and as indicated by step S3 of FIG. 3, the exposing unit 17 of the exposure apparatus 12 exposes a portion of the resist film R which is formed on the device area D. This exposure is made to obtain the fine pattern for forming the semiconductor device, for instance an immersion exposure. Thereby, a latent image of the fine pattern is formed in the portion of the resist film R which is formed on the device area D. In addition, an acid occurs in an exposed portion of the resist film R. On the other hand, another portion of the resist film R which is formed on the peripheral area E is left as an unexposed portion.

Subsequently, as indicated by step S4 of FIG. 3, the heating unit 18 in the exposure apparatus 12 heats the resist film R. The heating process is the mentioned above PEB and is made with conditions which enable an unreacted acid remaining in the resist film R to diffuse and react. These conditions cannot be uniformly determined as they differ depending on types of the resist material and the like. In general, however, the resist film R is heated to, for instance, a temperature in a range of 80 to 190° C. or more specifically, to, for instance, a temperature of 100° C. In this respect, because the exposing process indicated as step S3 and the heating process indicated as step S4 are performed by the same exposure apparatus 12, the heating process can be achieved immediately after the exposing process. For this reason, the acid having occurred in the exposed portion of the resist film R is allowed to diffuse by a predetermined diffusion length immediately after the exposing process, until being consumed. As a result, it is possible to suppress the variation in the diffusion of the acid, which may otherwise occur due to the variation in the waiting time before the subsequent heating process (step S7). This makes it possible to control the variation in the dimension of the reacted region in the resist film R. In other words, the heating process shown in step S4 is a reaction control process for controlling the dimension of the reacted region in the resist film R.

Afterward, as indicated by step S5 of FIG. 3, each 25 wafers, for instance, are contained in the transfer storage container 19, and are transferred from the exposure apparatus 12 to the coating/developing apparatus 11. Note that, depending on an usage condition of the coating/developing apparatus 11, the wafers W may be unable to be set inside the coating/developing apparatus 11 immediately after their transfer, and a waiting time may accordingly occur.

Afterward, as indicated by step S6 of FIG. 3, the exposing unit 14 in the coating/developing apparatus 11 exposes the portion of the resist film R which is formed on the peripheral area E. This exposure is made to obtain the dummy pattern for adjusting the coverage factor. The coverage factor of the dummy pattern is set at, for instance, 50%. Like the exposure of the device area D in step S3, this exposure of the dummy pattern in step S6 causes an acid in the exposed portion of the resist film R.

After that, as indicated by step S7 of FIG. 3, the heating unit 15 applies the heating process to the resist film M. This heating process is the mentioned above PEB. The heating conditions are set, for instance, equal to those for step S4. This causes the unreacted acid in the resist film R to diffuse and react. In this respect, because the exposing process indicated as step S6 and the heating process indicated as step S7 are performed in the same coating/developing apparatus 11, the heating process can be achieved immediately after the exposing process. This makes it easy to manage the time between the exposing process (step S6) and the heating process (step S7). For this reason, the acid having occurred in the exposed portion is allowed to react while the diffusion of the acid is being controlled. When this step is completed, both the fine pattern for forming the semiconductor device and the dummy pattern for adjusting the coverage factor are formed in the resist film R, as their respective latent images.

Subsequently, as indicated by step S8 of FIG. 3, the developing unit 16 develops the resist film R. Specifically, the resist film R is developed in tetra methyl ammonium hydroxide (TMAH) solution with a concentration of, for instance, 2.38 percent by mass for 30 seconds, and is thereafter rinsed with pure water. Thereby, the exposed portions are removed from the resist film R, and the resist pattern is thus formed. Note that the conditions, namely, a temperature, time, and other factors, for the heating process indicated as step S4 may be determined by taking into account the reacted area which is to be expanded on the heating process indicated as step S7 and the developing process indicated as step S8.

Afterward, various processes are applied to each wafer W by use of this resist pattern as the mask. For instance, ions of an impurity are doped into the wafer W while using the resist pattern formed on the wafer W as the mask. Thereby, the impurity is selectively doped into the wafer W so that a diffusion layer is formed in the wafer W. Otherwise, an interlayer dielectric film is etched while using the resist pattern formed on the interlayer dielectric film as the mask. Thereby, contacts holes are formed in the interlayer dielectric layer. In this respect, having formed the dummy pattern for adjusting the coverage factor on the peripheral area E of the wafer W inhibits the variation of the process conversion difference which may otherwise occur during the processes including the etching process. Accordingly, the wafer W can be processed uniformly. By repeating these processes, the device structure is formed inside and on top of the wafer W. Subsequently, the wafer W is diced, and semiconductor devices are thus manufactured.

Next, descriptions will be provided for effects of the embodiment.

In this embodiment, the process indicated a step S3 where the exposing unit 17 of the exposure apparatus 12 exposes the device area D in the wafer W is followed by the process indicated as step S4 where the heating unit 18 of the exposure apparatus 12 applies the heating process (PEB) on the resultant wafer W so that the acid which has occurred in the resist film R due to the exposure is eliminated during the heating process. For this reason, even if a waiting time occurs while the wafer W is transferred between the coating/developing apparatus 11 and the exposure apparatus 12, the acid does not diffuse inside the resist film R in the course of this waiting time, and thus the dimension of the resist pattern does not vary. Furthermore, performing the heating process immediately after the exposure in the same exposure apparatus 12 allows the time from the exposure to the heating process to be managed, thereby controlling the diffusion of the acid during this time.

As to the peripheral area E as well, the process indicated as step S6 where the exposing unit 14 installed in the coating/developing apparatus 11 exposes the peripheral area E of the wafer W is immediately followed by the process indicated as step S7 where the heating unit 15 installed in the same coating/developing apparatus 11 applies the heating process (PEB) on the wafer W. Because the exposure and the PEB are uninterruptedly carried out inside the same coating/developing apparatus 11 in this manner, the acid having occurred in the resist film R due to the exposure is allowed to react while being controlled so as to diffuse by a predetermined diffusion length, immediately after the exposure. This makes it possible to inhibit the variation in the dimension of the resist pattern which may otherwise occur due to the diffusion of the acid in the course of the waiting time.

Moreover, in this embodiment, the exposure of the device area D (step S3) precedes the exposure of the peripheral area E (step S6). This makes the time from the forming of the resist film R (step S1) to the exposing of the device area D (step S3) short. For this reason, the exposure of the device area D in which the finer pattern is formed can be achieved while change in the property of the resist film R is still small and while the conditions of the resist film R remain better.

In addition, in this embodiment, out of the units constituting the manufacturing system 1, the exposing unit 17 for performing the fine process is installed in the exposure apparatus 12, and is accordingly isolated from the coating/developing apparatus 11 which includes the other units, namely, the film forming unit 13, the exposing unit 14, the heating unit 15, and the developing unit 16. This configuration enables the exposure apparatus 12 and the coating/developing apparatus 11 to be operated independently. As a result, even if there is a difference between the throughput of the exposure apparatus 12 and the throughput of the coating/developing apparatus 11, the exposure apparatus 12 and the coating/developing apparatus 11 can be operated efficiently. Accordingly, it is possible to enhance the overall productivity of the manufacturing system 1.

Next, descriptions will be provided for a comparative example of the first embodiment.

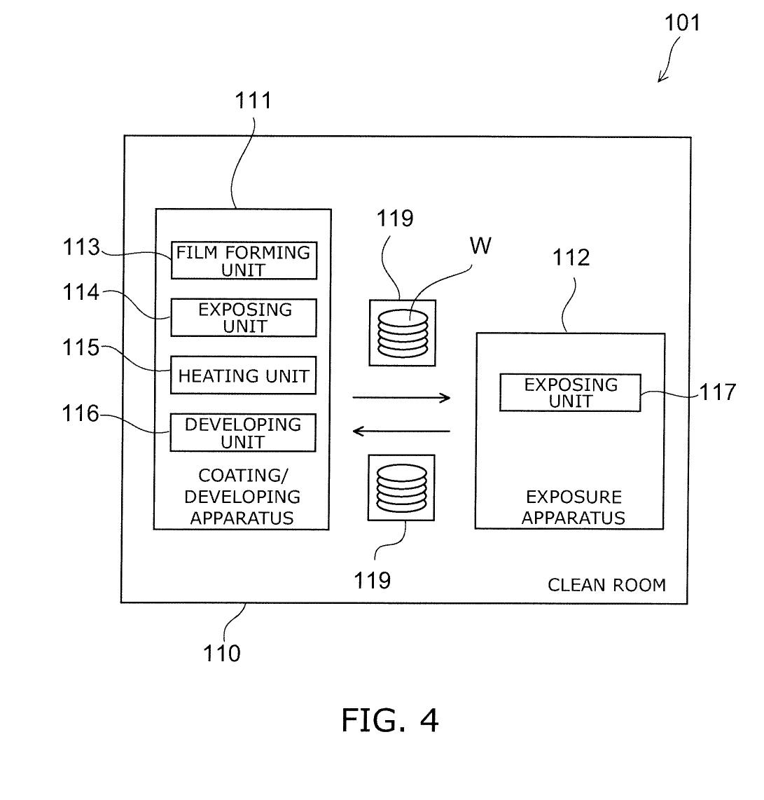

FIG. 4 is a block diagram illustrating a semiconductor device manufacturing system according to the comparative example.

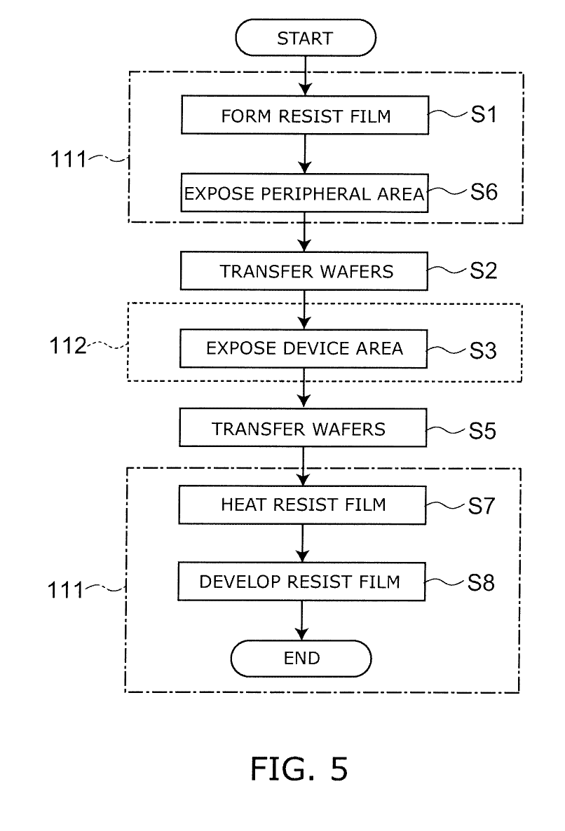

FIG. 5 is a flowchart illustrating a semiconductor device manufacturing method according to the comparative example.

Note that in FIG. 5, steps whose contents are the same as those of the steps shown in FIG. 3 are denoted by the same reference numerals for the sake of convenience.

As shown in FIG. 4, a clean room 110 is installed in the semiconductor device manufacturing system 101 according to the comparative example. A coating/developing apparatus 111 and an exposure apparatus 112 for the device area are installed in the clean room 110. In addition, the coating/developing apparatus 111 includes therein a film forming unit 113, an exposing unit 114 for the peripheral area, a heating unit 115, and a developing unit 116. Furthermore, a wafer W is transferred between the coating/developing apparatus 111 and the exposure apparatus 112 while contained in a transfer storage container 119. The exposure apparatus 112 includes only an exposing unit 117, but no heating unit.

Next, descriptions will be provided for the semiconductor device manufacturing method according to the comparative example.

First of all, as indicated by step S1 of FIG. 5, in the coating/developing apparatus 111, the film forming unit 113 forms a resist film R on the wafer W. Subsequently, as indicated by step S6 of FIG. 5, the exposing unit 114 exposes a portion of the resist film R which is formed on a peripheral area E to obtain a dummy pattern for adjusting a coverage factor.

Subsequently, as indicated by step S2, each batch of 25 wafers W, for instance, is contained in the transfer storage container 119, and is thus transferred from the coating/developing apparatus 111 to the exposure apparatus 112. However, depending on an usage condition of the exposure apparatus 112, the wafers W may be unable to be set inside the exposure apparatus 112 immediately after their transfer, and a waiting time may accordingly occur.

Thereafter, as indicated by step S3, the exposing unit 117 of the exposure apparatus 112 exposes a portion of the resist film R which is formed on a device area D to obtain a fine pattern for forming the semiconductor device.

Afterward, as indicated by step S5, the wafers are contained in the transfer storage container 119 again, and are transferred from the exposure apparatus 112 to the coating/developing apparatus 111. However, depending on an usage condition of the coating/developing apparatus 111, the wafers W may be unable to be set inside the coating/developing apparatus 111 immediately after their transfer, and a waiting time may accordingly occur.

After that, as indicated by step S7, the heating unit 115 of the coating/developing apparatus 111 heats the resist film R, and thus applies PEB to the resist film R. Subsequently, as indicated by step S8, the developing unit 116 develops the resist film R. Thereby, a resist pattern is formed on each wafer W.

In this comparative example, the exposure is applied to the peripheral area E in the coating/developing apparatus 111 (step S6); thereafter, the wafer W is transferred to the exposure apparatus 112 (step S2); the exposure is applied to the device area D (step S3); afterward, the wafer W is transferred back again to the coating/developing apparatus 111 (step S5); and the heating process (PEB) is applied to the wafer W (step S7). In other words, the wafer W is transferred between the coating/developing apparatus 111 and the exposure apparatus 112 twice after the peripheral area E is exposed, and once after the device area D is exposed before the PEB is applied to the wafer W.

The time from the exposure to the PEB varies from one transfer batch to another, because a waiting time is likely to occur each time a batch of wafers W is transferred as described above. In addition, although the exposure process is made through a sheet-fed process for each wafer W, the transfer is made for each batch with a predetermined number of wafers being contained in the transfer storage container at one time, and the heating process is made for each batch as well. For this reason, the time from the exposure to the PEB is different even in the same batch, between a wafer exposed at the first time and a wafer exposed at the last time, and thus varies from one wafer to another even in the same batch of wafers. This makes the diffusion condition of the acid having occurred due to the exposure differ from one wafer to another and allows the acid to react at an area which the acid reaches, thereby varying the dimension of the resist pattern from one wafer to another. Specifically, as the time from the exposure to the PEB becomes longer, the length of the diffusion of the acid becomes longer; correspondingly, a portion of the resist film R which reacts with the acid becomes larger; accordingly, a portion of the resist film which is removed by the development becomes more expanded; and consequently, a post-developed resist pattern becomes thinner. In this manner, the comparative example makes the dimension in the resist pattern vary from one wafer to another.

In contract, in the above first embodiment, because the PEB is carried out immediately after the exposure in the same apparatus, the time from the exposure to the PEB is shorter and uniform. For this reason, the first embodiment makes it possible to apply the heating process to each wafer before the unreacted acid diffuses, and accordingly to allow the acid to react while the diffusion through is controlled by this heating process. Accordingly, the first embodiment is capable of inhibiting the variation in the dimensional precision of the post-developed resist pattern.

Next, descriptions will be provided for a second embodiment of the invention.

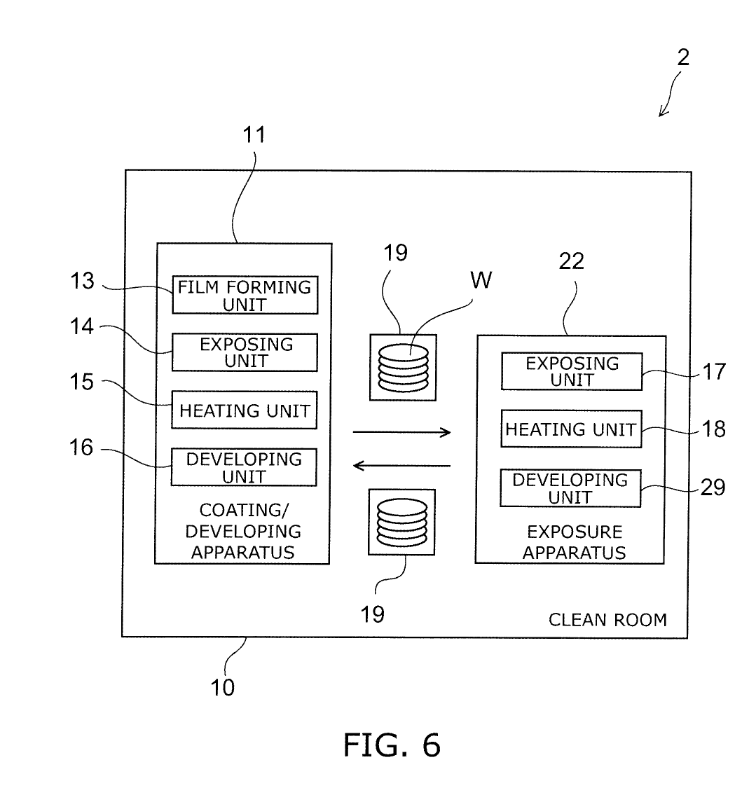

FIG. 6 is a block diagram illustrating a semiconductor device manufacturing system according to this embodiment.

As shown in FIG. 6, a semiconductor device manufacturing system 2 according to this embodiment is different from the semiconductor device manufacturing system 1 according to the first embodiment (refer to FIG. 1) in that the manufacturing system 2 includes an exposure apparatus 22 for a device area instead of the exposure apparatus 12 (refer to FIG. 1) for a device area. The exposure apparatus 22 includes a developing unit 29 in addition to the exposing unit 17 and the heating unit 18. The configuration of the manufacturing system according to this embodiment is identical with that of the manufacturing system according to the first embodiment other than the above-mentioned point.

Next, descriptions will be provided for a semiconductor device manufacturing method according to this embodiment.

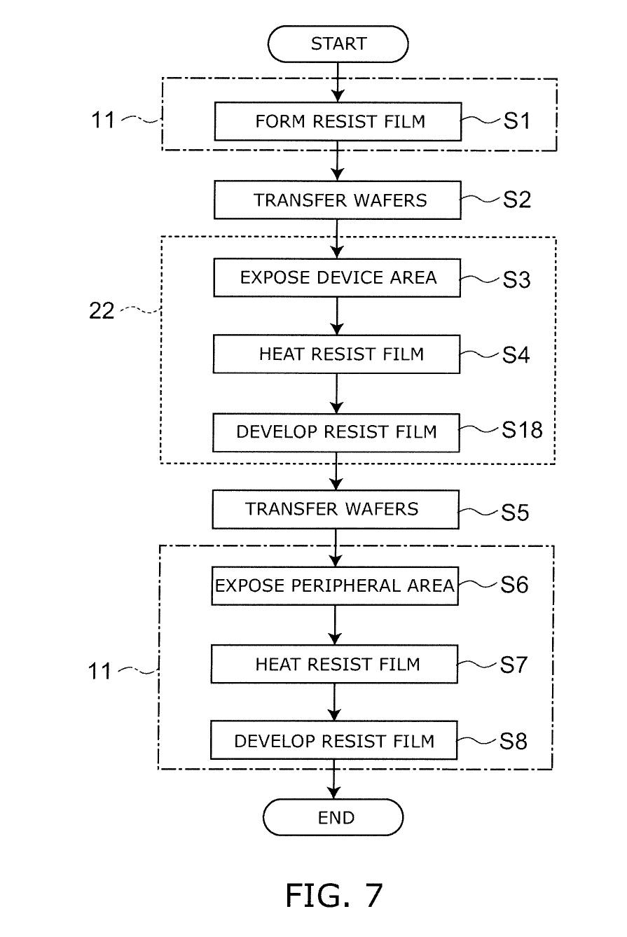

FIG. 7 is a flowchart illustrating the semiconductor device manufacturing method according to this embodiment.

As shown in FIG. 7, the semiconductor device manufacturing method according to this embodiment includes the same sequence as the semiconductor device manufacturing method according to the first embodiment (refer to FIG. 3), and further includes a developing process indicated as step S18 between the heating process indicated as step S4 and the transferring process indicated as step S5.

Specifically, in this embodiment, after the heating unit 18 of the exposure apparatus 22 heats the resist film R as indicated by step S4 of FIG. 7, a developing unit 29 of the exposure apparatus 22 develops the resist film R as indicated by step S18. Here, conditions for the development are set, for instance, the same as those for the development process indicated as step S8. Thereby, the resist pattern is formed in the device area D. It is noted that the resist film is formed from a positive type resist material and a portion which is formed on the peripheral area E is not removed by the development indicated as step S18 because the portion of the resist film which is formed on the peripheral area E is not exposed in step S3.

Subsequently, as in the first embodiment, the wafer W is transferred to the coating/developing apparatus 11 (step S5), and the exposing of the peripheral area E (step S6), the heating process (step S7), and the developing process (step S8) are carried out in the coating/developing apparatus 11. Thereby, the resist pattern is formed also in the peripheral area E. The manufacturing method according to this embodiment is identical to the manufacturing method according to the first embodiment other than the above-described point.

In this embodiment, the exposure apparatus 22 performs the exposure, PEB, and development on the device area D, and thereafter the coating/developing apparatus 11 performs the exposure, PEB, and development on the peripheral area E. This makes it possible to form the resist pattern in each area more stably. The effects of this embodiment are the same as those of the first embodiment, other than the above-described point.

Next, descriptions will be provided for a third embodiment of the invention.

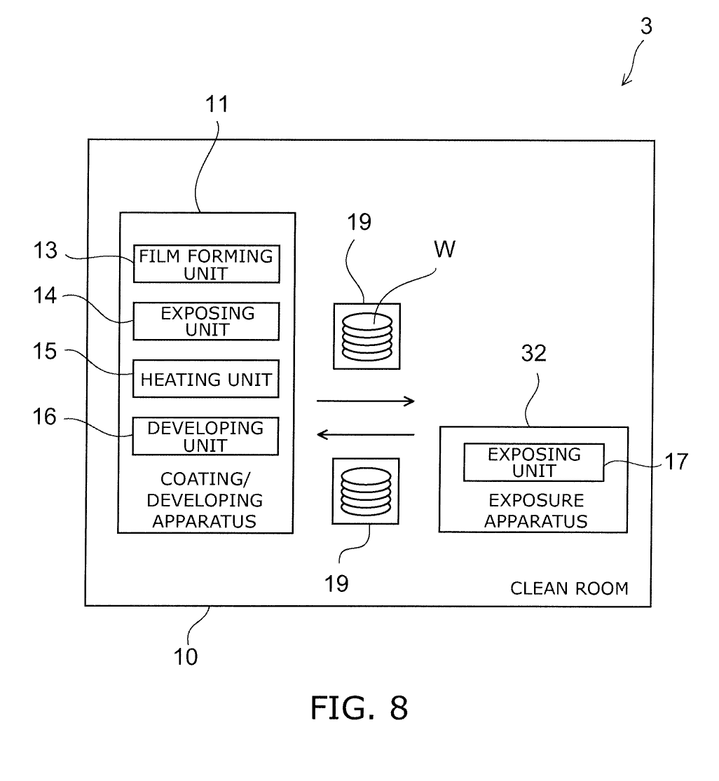

FIG. 8 is a block diagram illustrating a semiconductor device manufacturing system according to this embodiment.

As shown in FIG. 8, the semiconductor device manufacturing system 3 according to this embodiment is different from the semiconductor device manufacturing system 1 according to the first embodiment (refer to FIG. 1) in that the manufacturing system 3 includes an exposure apparatus 32 for a device area instead of the exposure apparatus 12 for a device area (refer to FIG. 1). The exposure apparatus 32 is different from the exposure apparatus 12 in that the exposure apparatus 32 includes only the exposing unit 17 but no heating unit 18 (refer to FIG. 1). The configuration of the manufacturing system according to this embodiment is the same as that of the manufacturing system according to the first embodiment other than the above-described point.

Next, descriptions will be provided for a semiconductor device manufacturing method according to this embodiment.

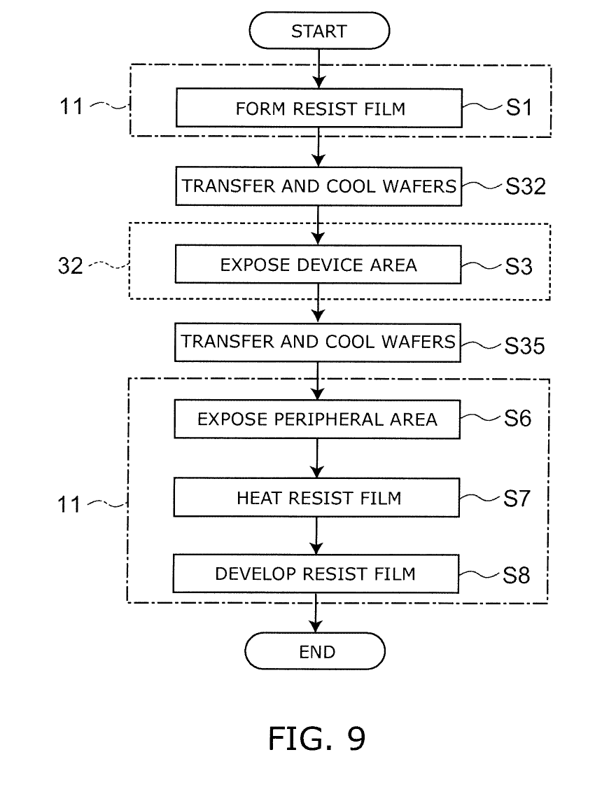

FIG. 9 is a flowchart illustrating the semiconductor device manufacturing method according to this embodiment.

As shown in FIG. 9, the semiconductor device manufacturing method according to this embodiment is different from the semiconductor device manufacturing method according to the first embodiment (refer to FIG. 3) in that the heating process indicated as step S4, namely the PEB which immediately follows the exposure of the device area D, is omitted. Instead of the PEB, in this embodiment, the room temperature of the clean room 10 is kept low. The room temperature of the clean room 10 is kept at, for instance, 10° C. or lower. This makes it possible to cool the resist film R with the air inside the clean room, and accordingly to inhibit dark reaction in the resist film R, during the transferring and waiting processes of the wafer W.

Specifically, in this embodiment, processes are carried out in the following manner. Firstly, as indicated by step S1 of FIG. 9, the film forming unit 13 forms the resist film R on the wafer W.

Subsequently, as indicated by step S32, the wafers W are transferred from the coating/developing apparatus 11 to the exposure apparatus 32 for the device area, and are caused to be kept waiting depending on the necessity. At this time, because the temperature inside the clean room 10 is kept at 10° C. or lower, the resist film R on each wafer W is cooled to a temperature, for instance, 10° C. or lower by being exposed to the air inside the clean room 10.

Thereafter, as indicated by step S3, the exposure apparatus 32 exposes the device area D of the wafer W.

Afterward, as indicated by step S35, without PEB being applied, the wafers W are transferred from the exposure apparatus 32 to the coating/developing apparatus 11, and are caused to be kept waiting depending on the necessity. At this time as well, the resist films R are cooled to a temperature 10° C. or lower, because the wafers W having been transferred out of the exposure apparatus 32 are exposed to the air inside the clean room 10. This makes it possible to inhibit the acid, which has occurred in the exposed portion of each resist film R during the exposing process indicated as step S3, from diffusing in the resist film R while the wafers W are transferred and are caused to be kept waiting.

The subsequent processes of the manufacturing method according to this embodiment are the same as those of the manufacturing method according to the first embodiment. Specifically, as indicated by step S6, the exposing unit 14 of the coating/developing apparatus 11 exposes the resist film R which is formed on the peripheral area E; and thereafter, as indicated by step S7, the heating unit 15 applies the heating process (PEB) to the resist film R. This causes the unreacted acid remaining in the resist film R to react in each of the peripheral area E and the device area D. Afterward, as indicated by step S8, the developing unit 16 develops the resist film R. Thereby, the resist pattern is formed on the wafer W. The manufacturing method according to this embodiment is the same as the manufacturing method according to the first embodiment, other than the above-described point.

Next, descriptions will be provided for the effects of this embodiment.

In the first and second embodiments, after the exposing process on the device area D indicated as step S3, the heating process (PEB) indicated as step S4 is carried out as the reaction control process for controlling the expansion of the reacted region in the resist film R. In contrast, in this embodiment, the resist film R is cooled as the reaction control process. In addition, the clean room 10 is used as the cooling apparatus for cooling the resist film R. As a result, even though the time from the exposure of the device area D (step S3) to the heating process for discontinuing the acid reaction (step S7) varies from one resist film to another, the diffusion of the acid in each resist film R is inhibited by keeping each resist film R at the low temperature during the time. In this manner, this embodiment makes it possible to prevent the variation in the dimension of the resist pattern.

Note that the conditions for cooling the resist film R should be determined such that the diffusion of the acid which occurs in the resist film R due to the exposure is inhibited. The conditions cannot be determined uniformly, because the conditions are different depending on the types of the resist material, the length of the waiting time, and other factors. Nevertheless, in general, when the temperature is set to 10° C. or lower, a considerable effect can be obtained. The effects of this embodiment are the same as those of the first embodiment, other than the above-described effect.

Next, descriptions will be provided for a fourth embodiment of the invention.

This embodiment is different from the third embodiment in that a storage container for storing a wafer is used as a cooling apparatus.

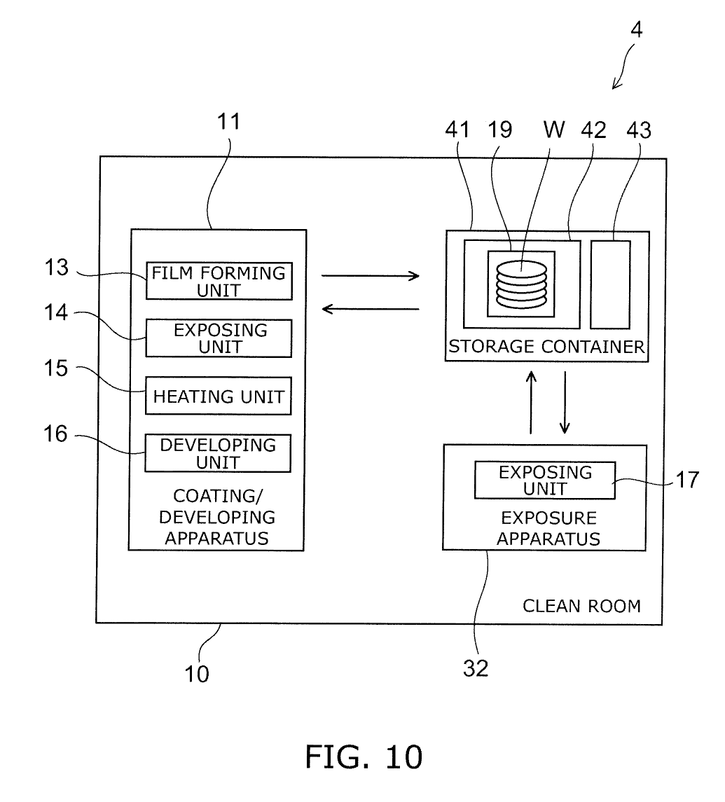

FIG. 10 is a block diagram illustrating a semiconductor device manufacturing system according to this embodiment.

As shown in FIG. 10, the semiconductor device manufacturing system 4 according to this embodiment has the same configuration as the semiconductor device manufacturing system 3 according to the third embodiment (refer to FIG. 8), and further includes a storage container 41 for storing a wafer W, which is provided between the coating/developing apparatus 11 and the exposure apparatus 32. The storage container 41 is fixedly installed in a predetermined location inside the clean room 10. The storage container 41 includes a storage section 42 for storing a wafer W, and a cooling section 43 for cooling the inside of the storage section 42.

Wafers W being required to be kept waiting in connection with their transfer between the coating/developing apparatus 11 and the exposure apparatus 32 are stored inside the storage section 42 of the storage container 41, being enclosed in the transfer storage container 19, for instance. The cooling section 43 supplies a gas, for instance, dry air or an inert gas, which is cooled to a temperature, for instance, 10° C. or lower to the inside of the storage section 42. The configuration of the manufacturing system according to this embodiment is the same as that of the manufacturing system according to the third embodiment other than the above-described point.

Next, descriptions will be provided for a semiconductor device manufacturing method according to this embodiment.

A flowchart illustrating the semiconductor device manufacturing method according to this embodiment is the same as that shown in FIG. 9.

In this embodiment, the temperature inside the clean room 10 is set to the room temperature, for instance, to 23° C. In each of the transferring/cooling processes respectively indicated as step S32 and S35 in FIG. 9, wafers W in waiting which are enclosed in the transfer storage container 19 are contained in the storage section 42 of the storage container 41. The cooling section 43 supplies a cooled gas to the inside of the storage section 42, and thereby cools the wafers W stored inside the storage section 42, together with their resist films R. This inhibits the diffusion of the acid in each resist film R. Note that, in a case where the wafers W are not required to be kept waiting, the wafers W are not stored in the storage container 41, and thus are not cooled. In this case, however, no problem occurs because the time from the exposure to the PEB is manageable uniformly. The manufacturing method according to this embodiment is the same as the manufacturing method according to the third embodiment, other than the above-described point. Effects similar to those of the third embodiment can be obtained from this embodiment.

Next, descriptions will be provided for a fifth embodiment of the invention.

In this embodiment, a transfer storage container for transferring a wafer W is used as a cooling apparatus.

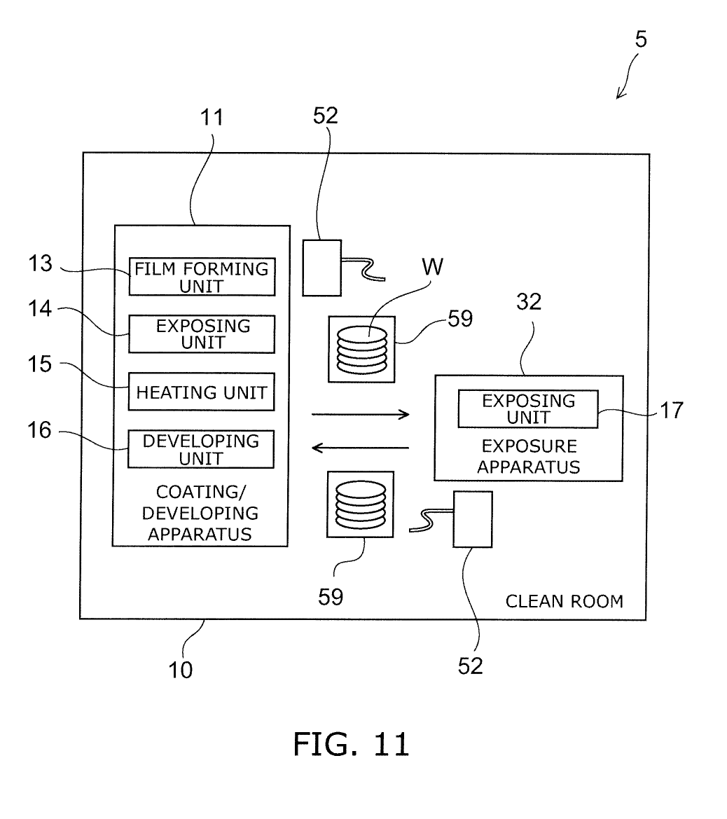

FIG. 11 is a block diagram illustrating a semiconductor device manufacturing system according to this embodiment.

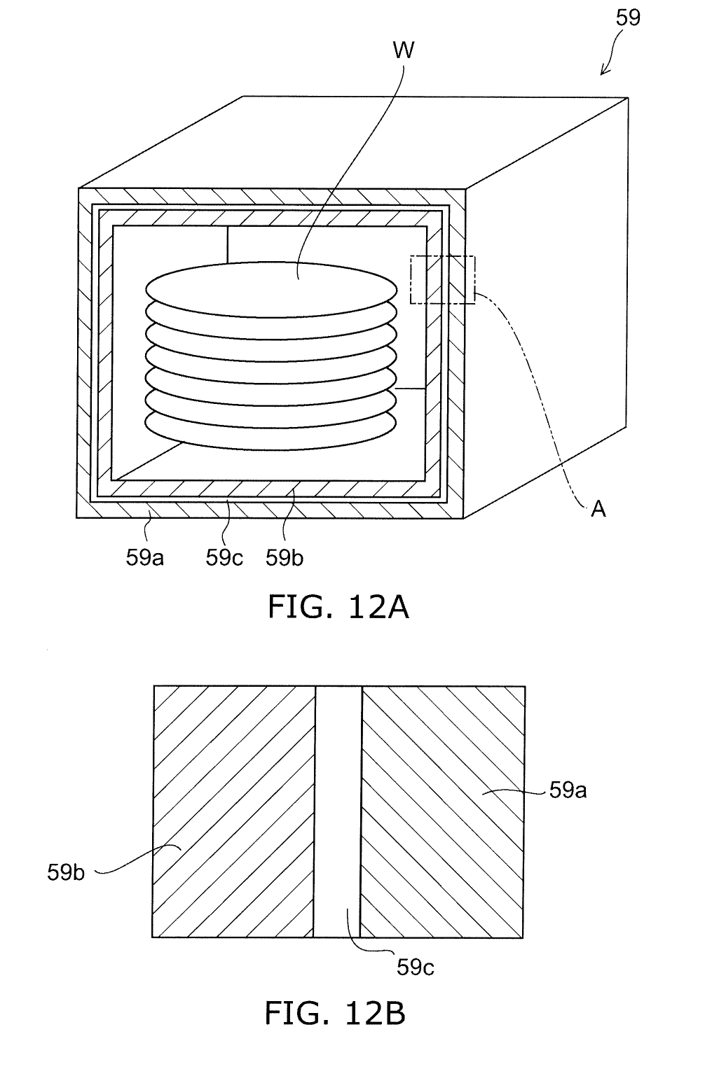

FIG. 12A is a perspective, cross-sectional view showing a transfer storage container according to this embodiment, and FIG. 12B is a partially magnified cross-sectional view of an area A shown in FIG. 12A.

As shown in FIG. 11, a semiconductor device manufacturing system 5 according to this embodiment is different from the semiconductor device manufacturing system 3 according to the third embodiment (refer to FIG. 8) in that the manufacturing system 5 includes a transfer storage container 59 having a cooling function instead of the transfer storage container 19 (refer to FIG. 8). In addition, in the manufacturing system 5, cooling gas supplying apparatuses 52 are respectively installed near the coating/developing apparatus 11 and the exposure apparatus 32. Each cooling gas supplying apparatus 52 supplies a cooled gas, for instance, dry air or a inert gas to the inside of the transfer storage container 59.

As shown in FIGS. 12A and 12B, each transfer storage container 59 has a box-shaped internal wall 59b installed inside a box-shaped external wall 59a, and multiple wafers W are stored inside the internal wall 59b. A space 59c is formed between the external wall 59a and the internal wall 59b. The inside of the space 59c is evacuated. Thereby, the space 59c serves as a vacuum layer. Instead of the vacuum layer, a heat-insulating material layer may be provided in the space 59c by filling the space 59c with a heat-insulating material, or both the vacuum layer and the heat-insulating material layer may be provided in the space 59c.

Next, descriptions will be provided for a semiconductor device manufacturing method according to this embodiment.

A flowchart illustrating the semiconductor device manufacturing method according to this embodiment is the same as that shown in FIG. 9.

In this embodiment, the temperature inside the clean room 10 is set to the room temperature, for instance, to 23° C. In each of the transferring/cooling processes respectively indicated as step S32 and S35 in FIG. 9, a predetermined number of wafers W are contained in the transfer storage container 59. At this time, the cooling gas supplying apparatus 52 fills the cooled dry air or the cooled inert gas, for instance, at a temperature 10° C. or lower, into the inside of the transfer storage container 59, and thereafter closes the transfer storage container 59 hermetically. Subsequently, the wafers W enclosed in the transfer storage container 59 are transferred as they are, and are caused to be kept waiting depending on the necessity.

At this time, the wafers W and their resist films R are both cooled with the cooled gas which is filled in the inside of the transfer storage container 59. In addition, the transfer storage container 59 has a high heat-insulating characteristic, and is accordingly capable of keeping the resist films R at the low temperature for a long time, because the vacuum layer or the heat-insulating material layer is formed in the space 59c. The manufacturing method according to this embodiment is the same as the manufacturing method according to the third embodiment, other than the above-described point. Effects similar to those of the third embodiment can be obtained from this embodiment.

Next, descriptions will be provided for a sixth embodiment of the invention.

A semiconductor device manufacturing system according to this embodiment is identical to the semiconductor device manufacturing system according to the first embodiment (refer to FIG. 1).

Hereinafter, descriptions will be provided for a semiconductor device manufacturing method according to this embodiment.

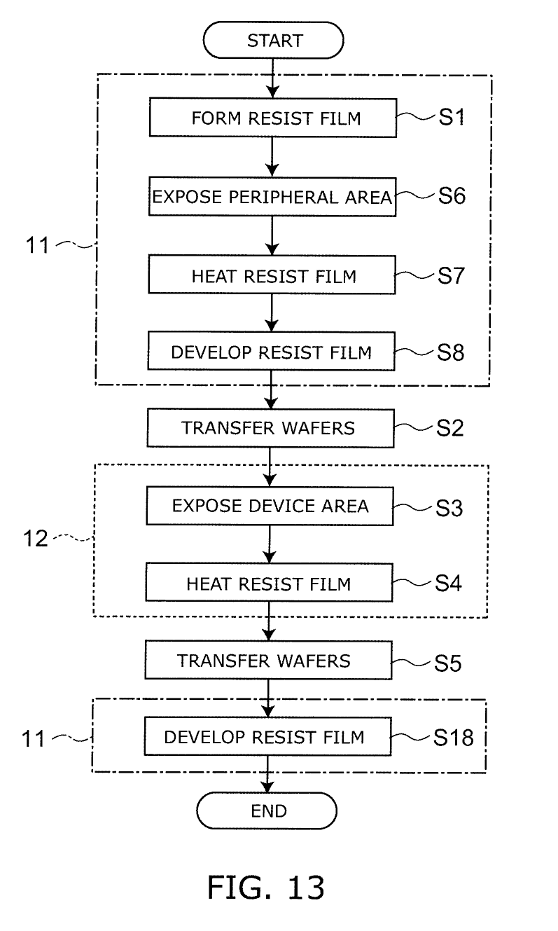

FIG. 13 is a flowchart illustrating the semiconductor device manufacturing method according to this embodiment.

As shown in FIG. 13, the semiconductor device manufacturing method according to this embodiment is different from the semiconductor device manufacturing method according the second embodiment in that the sequence of the exposing process applied to the device area D (step S3) and the sequence of the exposing process applied to the peripheral area E (step S6) are exchanged for each other. In addition, because of the exchange, the timing of the transfer of the wafers W is different from that in the manufacturing method according to the second embodiment. In this embodiment, the heating process is performed as the reaction control process.

Detailed description will be provided hereinbelow.

In this embodiment, the temperature inside the clean room 10 is set to the room temperature, for instance, 23° C.

Subsequently, as indicated by step S1 of FIG. 13, in the coating/developing apparatus 11, the film forming unit 13 forms the resist film R throughout the top surface of the wafer W.

Subsequently, as indicated by step S6, the exposing unit 14 exposes a portion of the resist film R which is formed in the peripheral area E. Thereby, the latent image of the dummy pattern for adjusting a coverage factor is formed on the peripheral area E.

Thereafter, as indicated by step S7, the heating unit 15 heats the resist film R to a temperature, for instance, in a range of 80 to 190° C. or more specifically, for instance, to a temperature of 100° C. In this respect, the unreacted acid in the resist film R is allowed to react while being controlled so as to diffuse by a predetermined diffusion length, because the exposing of the resist film R by the exposing unit 14 is immediately followed by the heating of the resist film R by the heating unit 15 in the same coating/developing apparatus 11.

Afterward, as indicated by step S8, the developing unit 16 develops the resist film R. Thereby, the exposed portion of the resist film R is removed, and the dummy pattern for adjusting the coverage factor is thus formed on the peripheral area E of the wafer W.

After that, as indicated by step S2, the wafers W are transferred from the coating/developing apparatus 11 to the exposure apparatus 12 by use of the transfer storage container 19. At this time, a waiting time is likely to occur depending on an usage condition of the exposure apparatus 12. However, the dimension of their resist patterns does not change with time, because the reaction of the acid and the development have been completed in the peripheral area E.

Subsequently, as indicated by step S3, the exposing unit 17 of the exposure apparatus 12 exposes a portion of the resist film R which is formed on the device area D. This exposure is made to obtain a fine pattern for forming the semiconductor device, and is, for instance, an immersion exposure. By this exposure, the latent image of the fine pattern is formed in the device area D.

Thereafter, as indicated by step S4, the heating unit 18 of the exposure apparatus 12 heats the resist film R to a temperature, for instance, in a range of 80 to 190° C., or more specifically, to, for instance, a temperature of 100° C. In this respect, the heating process can be achieved within a period where scarcely any unreacted acid in the resist film R diffuses, because the exposing of the resist film R by the exposing unit 17 is immediately followed by the heating of the resist film R by the heating unit 18 in the same exposure apparatus 12.

Afterward, as indicated by step S5, the wafers W are transferred from the exposure apparatus 12 to the coating/developing apparatus 11 by use of the transfer storage container 19. At this time, a waiting time is likely to occur depending on an usage condition of the coating/developing apparatus 11. However, the dimension of the latent image does not change due to the advancement of the reaction of the acid, because the reaction of the acid has been completed in the device area D.

After that, as indicated by step S18, the developing unit 16 of the coating/developing apparatus 11 develops the resist film R. Thereby, the fine pattern for forming the semiconductor device is formed on the device area D of the wafer W. The subsequent processes of the manufacturing method are identical to those of the manufacturing method according to the first embodiment. The manufacturing method according to this embodiment is the same as the manufacturing method according to the first embodiment, other than the above-described point. Furthermore, in this embodiment the resist film R whose peripheral area has been exposed in the process indicated as step S8, is developed so that the exposed portion of the resist film R is removed. For this reason, when the immersion exposure is applied to the device area D in the process indicated as step S3, no exposed portion of the resist film R dissolves into a fluid used for the immersion exposure. The effects of this embodiment are the same as those of the second embodiment, other than the above-described point.

Next, descriptions will be provided for a seventh embodiment of the invention.

A semiconductor device manufacturing system according to this embodiment is identical to the semiconductor device manufacturing system according to the third embodiment (refer to FIG. 8). Specifically, in this embodiment, the resist film R is cooled by the clean room 10 as the reaction control process.

Hereinbelow, descriptions will be provided for a semiconductor device manufacturing method according to this embodiment.

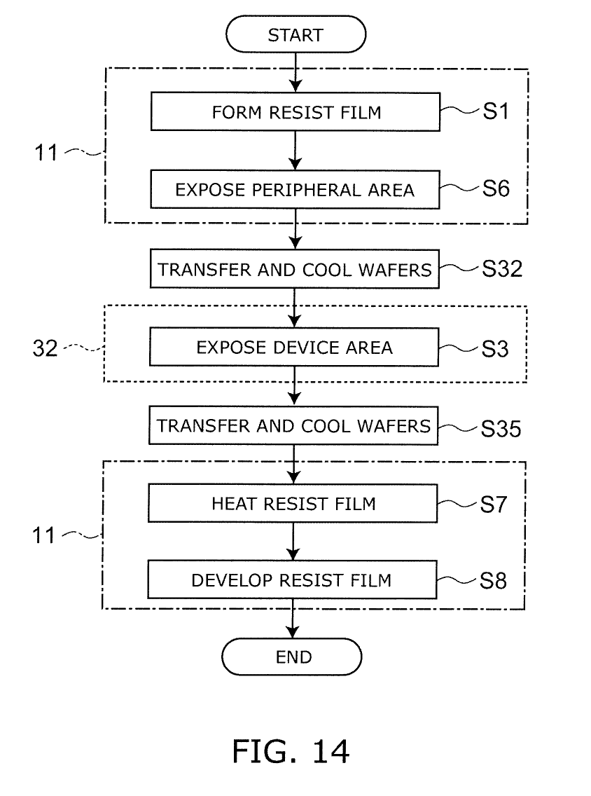

FIG. 14 is a flowchart illustrating the semiconductor device manufacturing method according to this embodiment.

As shown in FIG. 14, the semiconductor device manufacturing method according to this embodiment is different from the semiconductor device manufacturing method according to the third embodiment (refer to FIG. 9) in that the sequence of the exposing process applied to the device area D (step S3) and the sequence of the exposing process applied to the peripheral area E (step S6) are exchanged for each other. In addition, because of the exchange, the timing of the transfer of the wafers W is different from that of the manufacturing method according to the third embodiment.

Detailed descriptions will be provided hereinbelow.

In this embodiment, the temperature inside the clean room 10 is set to, for instance, 10° C. or lower.

Subsequently, as indicated by step 51 of FIG. 14, in the coating/developing apparatus 11, the film forming unit 13 forms the resist film R throughout the top surface of the wafer W.

Thereafter, as indicated by step S6, the exposing unit 14 exposes a portion of the resist film R which is formed on the peripheral area E.

Afterward, as indicated by step S32, without PEB being applied, the wafers W are transferred from the coating/developing apparatus 11 to the exposure apparatus 32 for a device area by use of the transfer storage container 19, and are caused to be kept waiting depending on the necessity. In this respect, the diffusion of the acid is inhibited while the wafers W are in the course of being transferred and in waiting, because their resist films R are cooled in the clean room 10 having the temperature set to 10° C. or lower.

After that, as indicated by step S3, the exposure apparatus 32 exposes the device area D of each wafer W.

Subsequently, as indicated by step S35, without PEB being applied, the wafers W are transferred from the exposure apparatus 32 to the coating/developing apparatus 11 by use of the transfer storage container 19, and are caused to be kept waiting depending on the necessity. At this time as well, the wafers W having been transferred out of the exposure apparatus 32 and their resist films R are cooled with the air inside the clean room 10, and thus the diffusion of the acid is inhibited while the wafers W are in the course of being transferred and in waiting.

Thereafter, as indicated by step S7, the heating unit 15 applies the heating process (PEB) to the resist film R. Thereby, all the unreacted acid is caused to react.

Afterward, as indicated by step S8, the developing unit 16 develops the resist film R. Thereby, the resist pattern is formed on the wafer W. The manufacturing method according to this embodiment is the same as the manufacturing method according to the third embodiment, other than the above-described point.

As in the third embodiment, this embodiment is capable of inhibiting the diffusion of the acid by cooling the resist film R, and accordingly of controlling the expansion of the reacted region in the resist film R. This makes it possible to prevent the dimension of the resist pattern from varying due to the variation in the waiting time. The effects of this embodiment are the same as those of the first embodiment, other than the above-described point.

Note that, although this embodiment illustrates a case where the wafer is cooled while being transferred and in waiting by lowering the temperature inside the clean room, the method of cooling the wafer is not limited thereto. For instance, the post-exposed resist film may be cooled by use of the storage container for storing a wafer as in the case of the fourth embodiment. Otherwise, the resist film may be cooled by use of the transfer storage container which is used to transfer a wafer as in the case of the fifth embodiment.

The first, the second, and the sixth embodiments employ a method in which the reaction of the acid is accelerated by heating the resist film to, for instance, a temperature in a range of 80 to 190° C. immediately after the exposure so that the acid is allowed to react with its diffusion length being controlled as the method of controlling the expansion of the reacted region in the resist film. In contrast, the third, the fourth, the fifth, and the seventh embodiments employ a method in which the resist film is cooled to, for instance, a temperature 10° C. or lower for a time period from the exposing process to the heating process so that the diffusion of the acid is inhibited. Nevertheless, the temperature range is not limited to these instances, because the temperature range varies depending on factors such as the types of the resist material and the length of the waiting time. Furthermore, a process other than the heating process and the cooling process may be employed as the process of controlling the expansion of the reacted region in the resist film.

Furthermore, each of the first, the second, and the sixth embodiments shows a case where the heating process (PEB) following the exposure of the device area and the heating process (PEB) following the exposure of the peripheral area are made at the same temperature. Nevertheless, the invention is not limited thereto. The temperature may be different between the two heating processes. For instance, the dummy pattern formed in the peripheral area E requires the dimensional precision which is not as high as the dimensional precision required for the fine pattern for forming the semiconductor device formed in the device area D. For this reason, all the unreacted acid needs not to be reacted in the heating process following the exposure of the peripheral area E in some cases. In this case, the temperature for the heating process following the exposure of the peripheral area E may be set lower. Similarly, the time periods for the respective heating processes (PEBs) may be set independently of each other. For instance, these factors may be predetermined in advance in such a way that the resist pattern to be formed can have a desired dimension.

Moreover, each of the above-described embodiments shows a case where the chemically-amplified ArF resist is used as the resist material. Nevertheless, the invention is not limited thereto. Instead, a resist material of a negative type may be used for the first, the third, the fourth, the fifth, and the seventh embodiments.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the invention.

1. A method for manufacturing a semiconductor device comprising:
forming a resist film on a substrate;
exposing a portion of the resist film, the portion being formed on a device area of the substrate, the device area including a center portion of the substrate;
after the exposing the device area, applying a reaction control process for controlling expansion of a reacted region in the resist film;
after the applying the reaction control process, exposing another portion of the resist film, the another portion being formed on a peripheral area surrounding the device area;
after the exposing the peripheral area, heating the resist film; and
after the heating, developing the resist film.

2. The method according to claim 1, wherein
the reaction control process is a process to heat the resist film.

3. The method according to claim 2, wherein
the exposing the device area and the applying the reaction control process are both achieved by an identical apparatus.

4. The method according to claim 2, further comprising
developing the resist film after the applying the reaction control process and before the exposing the peripheral area,
the resist film being of a positive type.

5. The method according to claim 2, wherein
the reaction control process is applied with conditions enabling an acid to react, the acid having occurred in the resist film due to the exposing the device area.

6. The method according to claim 1, wherein
the reaction control process is a process to cool the resist film.

7. The method according to claim 6, wherein
the reaction control process is applied with conditions inhibiting diffusion of an acid having occurred in the resist film due to the exposing the device area.

8. A method for manufacturing a semiconductor device comprising:
forming a positive type resist film on a substrate;
exposing a portion of the resist film, the portion being formed on a peripheral area of the substrate, the peripheral area surrounding a device area of the substrate, the device area including a center portion of the substrate;
after the exposing the peripheral area, performing a first heating process to heat the resist film;
after the first heating process, performing a first developing process to develop the resist film;
after the first developing process, exposing another portion of the resist film, the another portion being formed on the device area;
after the exposing the device area, performing a second heating process to heat the resist film; and
after the second heating process, performing a second developing process to develop the resist film.

9. The method according to claim 8, wherein
the exposing the portion formed on the device area is achieved by immersion exposure.

10. A method for manufacturing a semiconductor device comprising:
forming a resist film on a substrate;
exposing a part of the resist film;
after the exposing, cooling the resist film;
after the cooling, heating the resist film; and
after the heating, developing the resist film.

11. The method according to claim 10, wherein
the part of the resist film is a portion formed on a device area of the substrate, the device area including a center portion of the substrate.

12. The method according to claim 10, further comprising
exposing another part of the resist film before the exposing the part of the resist film.

13. The method according to claim 12, further comprising
another cooling the resist film after the exposing the another part of the resist film and before the exposing the part of the resist film,
the part of the resist film being a portion formed on a device area of the substrate, the device area including a center portion of the substrate, and
the another part of the resist film is a portion formed on a peripheral area around the device area.

14. A system of manufacturing a semiconductor device comprising:
a film forming unit configured to form a resist film on a substrate;
a first exposing unit configured to expose a portion of the resist film, the portion being formed on a device area of the substrate, the device area including a center portion of the substrate;
a first heating unit configured to heat the resist film;
a second exposing unit configured to expose another portion of the resist film, the another portion being formed on a peripheral area of the substrate, and the peripheral area surrounding the device area;
a second heating unit configured to heat the resist film; and
a developing unit configured to develop the resist film,
the first exposing unit and the first heating unit being installed in a first apparatus, and
the second exposing unit and the second heating unit being installed in a second apparatus.

15. The system according to claim 14, wherein
the film forming unit and the developing unit are installed in the second apparatus.

16. A system of manufacturing a semiconductor device comprising:
a film forming unit configured to form a resist film on a substrate;
an exposing unit configured to expose a portion of the resist film, the portion being formed on a device area of the substrate, the device area including a center portion of the substrate;
a heating unit configured to heat the resist film;
a developing unit configured to develop the resist film; and
a cooling apparatus configured to cool the resist film,
the cooling apparatus cooling the resist film at least after the exposing unit exposes the resist film and before the heating unit heats the resist film.

17. The system according to claim 16, wherein
the cooling apparatus is a storage container for storing the substrate.

18. The system according to claim 16, wherein
the cooling apparatus includes:
a transfer storage container which is conveyed with the substrate being stored in an inside of the transfer storage container; and
a cooling gas supplying apparatus configured to supply a cooled gas to the inside of the transfer storage container.

19. The system according to claim 18, wherein
the transfer storage container includes:
an external wall;
an internal wall installed inside the external wall, the substrate being stored inside the internal wall; and
a heat-insulating layer installed in a space between the external wall and the internal wall.

20. The system according to claim 16, further comprising
another exposing unit configured to expose another portion of the resist film, the another portion being formed on a peripheral area of the substrate, and the peripheral area surrounding the device area,
the film forming unit, the another exposing unit, the heating unit, and the developing unit are installed in an identical apparatus.
